(19) United States
(12) Patent Application Publication
(10) Pub. No.: US 2008/0135177 A1
(43) Pub. Date: Jun. 12, 2008

(54) PLASMA PROCESSING APPARATUS

(75) Inventor: Sung Ryul Kim, Seongnam-Si (KR)

Correspondence Address: MARGER JOHNSON & MCCOLLOM, P.C., 210 SW MORRISON STREET, SUITE 400, PORTLAND, OR, 97204, US

(73) Assignee: TES CO., LTD., Yongjn-Si (KR)

(21) Appl. No.: 11/947,610

(22) Filed: Nov. 29, 2007

(30) Foreign Application Priority Data
Dec. 8, 2006 (KR) 10-2006-0124763
Aug. 24, 2007 (KR) 10-2007-0085561

(51) Int. Cl. H01L 21/306

(52) U.S. Cl. 156/345.43

(57) ABSTRACT

A plasma processing apparatus includes: a chamber; an insulating member disposed in an upper portion of the chamber; a ground electrode formed at a side wall of the chamber, a ground potential being applied to the ground electrode; and a lower electrode disposed in a lower portion of the chamber, a substrate being placed on the lower electrode, wherein the lower electrode is divided into a plurality of electrodes.

According to an aspect of the present invention, particles accumulated in the central portion on a lower surface, an edge area of an upper surface, a side, and an edge area of the lower surface of the substrate can be effectively removed.

### BACKGROUND OF THE INVENTION

1. Field of the Invention

The present invention relates to a plasma processing apparatus, particularly a plasma processing apparatus that removes a variety of impurities on a substrate.

2. Description of the Related Art

Semiconductor elements and flat panel displays are formed by depositing a plurality of thin films on a substrate and etching the films. That is, an element having a predetermined thin film pattern is formed by depositing thin films on a predetermined region of a substrate, mainly in the central region, and then removing a portion of the thin films in the central region of the substrate by etching with an etching mask.

The thin film is deposited on the entire substrate during deposition, whereas an etching target during etching is a portion of the thin film in the central region of the substrate. Accordingly, the rest of the thin film in an edge area of the substrate is not removed and particles are accumulated in the edge area of the substrate as the etching process is continued. Further, since the substrate is typically seated by an electrostatic force or a vacuum force on a substrate holder for supporting the substrate, the substrate and the substrate holder are spaced apart by a predetermined distance so that a gap is formed at the interface. Therefore, the particles and thin films are also accumulated on the entire rear surface of the substrate.

Therefore, when the process is continued without removing the particles and thin films accumulated on the substrate, the substrate may be deformed or alignment of the substrate may become difficult.

In general, a wet etching and a dry etching are known in the art as methods of removing particles and thin films accumulated on the substrate. The wet etching removes particles on a surface by soaking a substrate in a solvent or a rinse, and the dry etching removes particles by etching the surface with plasma.

Although the wet etching is generally used to remove particles accumulated on the surface of the substrate, it is difficult to selectively remove the particles in the edge area since process management of the wet etching is difficult. Further, the wet etching process results in an increase of the process cost by using a large amount of chemicals and causes many environmental problems such as chemical waste disposal. On the contrary, dry etching removes particles and thin films accumulated around the edge of a substrate using plasma, and may avoid drawbacks of the wet etching. Therefore, in recent years, an apparatus for exposing and etching only an edge area of a substrate is under development.

In the related art, plasma etching devices for etching an edge area of a substrate using plasma as described above have been disclosed in Korean Patent Registration Nos. 10-043308 and 10-0442194.

According to a device disclosed in Korean Patent Registration No. 10-043308, a stage has a smaller diameter than a substrate, and a distance between a stage and an insulator is set to be smaller than a distance between a cathode ring and an anode ring. The cathode ring and anode ring are attached to the outsides of the stage and insulator, respectively. In detail, the anode ring is installed around a circumference of the insulator. A view ring is coaxially attached around the circumference of the anode ring so that an edge of the view ring extends to be close to the cathode ring. Therefore, the circumference of the stage is shielded except for a predetermined gap between the stage and the cathode ring. An RF output terminal is connected to the cathode ring. In the above configuration, the cathode ring and anode ring are installed around the circumferences of the stage and insulator, respectively. The diameters of the stage and insulator are smaller that that of a substrate. And plasma is generated by a discharge between the cathode ring and the anode ring. In addition, the view ring is installed around the cathode ring, so that the plasma is applied even to the edge area of the lower surface of the substrate. Thereby the edge area of the lower surface of the substrate can be effectively etched using the plasma.

A pair of electrodes, i.e., first and second electrodes for dry etching of a substrate is disclosed in Korean Patent Registration No. 10-0442194. The first and second electrodes are facing each other, and remove impurities on an edge area the substrate by generating plasma. The first electrode includes a first protruding end and a first protrusion. The first protruding end and the first protrusion have a circular shape, and face one side of upper and lower portions of the edge of the substrate. The second electrode includes a second protruding end and a second protrusion. The second protruding end and the second protrusion have the same size as the first protruding end the first protrusion, and face the other side of the upper and lower portions of the edge of the substrate. According to the above configuration, a variety of impurities accumulated on sides and a lower surface of an edge area of a substrate, not to mention an upper surface, can be removed.

However, in the above configurations in the related arts, a substrate is placed on a substrate holder having a smaller diameter than the substrate, and then a portion of the substrate which is exposed to the plasma is etched by plasma. As such, particles accumulated on an edge area, sides, and a lower surface of the substrate, in particular, particles accumulated on an edge area of the lower surface are removed. However, particles accumulated between the substrate holder and the substrate are not easily removed in the above configuration.

### SUMMARY OF THE INVENTION

The present invention provides a plasma processing apparatus which effectively removes not only particles on an edge area of an upper surface, sides, and a lower surface of a substrate, but also particles accumulated in a central region of the lower surface of the substrate.

According to an aspect of the present invention, a plasma processing apparatus includes a chamber; an insulating member disposed in an upper portion of the chamber; a ground electrode formed at a side wall of the chamber, a ground potential being applied to the ground electrode; and a lower electrode disposed at a lower portion of the chamber, a substrate being placed on the lower electrode, wherein the lower electrode is divided into a plurality of electrodes. The plurality of electrodes includes an inner electrode and an outer electrode and the inner electrode and the outer electrode may be coaxially spaced from each other.

A lift member that moves up/down the lower electrode is further provided under the lower electrode. The lift member alternately may move up/down the inner electrode and the outer electrode. A ground electrode may be further formed between the insulating member and the inside of the chamber. A gas supply channel is formed in the ground electrode and a gas supplier may be connected with the gas supply channel. The lift member is connected to the inner electrode and another upper lift member that moves up/down the insulating member may be further included. The outer electrode is supported by an electrode support, a focus ring may be further provided around the outside of the outer electrode, and a vent plate may be further provided between the focus ring and the inner wall of the chamber.

Gas injection holes are formed in the plurality of the electrodes and the gas injection holes may be formed on the outside of the inner electrode and the inside of the outer electrode. An intermediate electrode is further provided between the inner electrode and the outer electrode and gas injection holes may be further formed on the inside and the outside of the intermediate electrode.

An intermediate electrode may be further included between the inner electrode and the outer electrode. The diameter of the intermediate electrode may be in a range of 56% to 70% of a diameter of the outer electrode. The diameter of the inner electrode may be in a range of 40% to 56% of the diameter of the outer electrode. The diameter of the inner electrode may be in a range of 120 mm to 170 mm; the diameter of the intermediate electrode may be in a range of 170 mm to 210 mm; and the diameter of the outer electrode may be in a range of 210 mm to 300 mm. The distances between the inner electrode and the intermediate electrode, and between the intermediate electrode and the outer electrode may be in a range of 0.1 mm to 10 mm.

The insulating member may include an inner insulating member and an outer insulating member which is coupled to an outer circumference of the inner insulating member. A groove and a protrusion corresponding to each other may be formed on an upper surface of the insulating member and a lower surface of the chamber lid, respectively, and the upper surface of the insulating member may be coupled with lower surface of the chamber lid. A gas injector ring may be further provided to a lower surface of the inner insulating member. A lower groove having a shape of a looped curve is formed on the lower surface of the inner insulating member. The gas injector ring may be inserted into the lower groove. A gas line may be further formed through the insulating member to communicate with the lower groove.

### BRIEF DESCRIPTION OF THE DRAWINGS

The above and other features and advantages of the present invention will become more apparent by describing in detail preferred embodiments thereof with reference to the attached drawings in which:

FIG. 1 is a cross-sectional view of a plasma processing apparatus according to a first exemplary embodiment of the present invention;

FIG. 2 is a perspective view showing a variant of an insulating member provided in the plasma processing apparatus according to the first exemplary embodiment of the present invention;

FIG. 3 is a cross-sectional view showing the insulating member of FIG. 2 attached to a chamber;

FIG. 4 is a cross-sectional view of a first variant of the insulating member provided in the plasma processing apparatus according to the first exemplary embodiment of the present invention;

FIG. 5 is a cross-sectional view of a second variant of the insulating member provided in the plasma processing apparatus according to the first exemplary embodiment of the present invention;

FIG. 6 is a rear perspective view of a gas injector ring shown in FIG. 5;

FIG. 7 is an exploded perspective view of a lower electrode according to the first exemplary embodiment of the present invention;

FIGS. 8 to 11 are schematic cross-sectional views illustrating a process of removing impurities on a side and a lower surface of a substrate;

FIGS. 12 to 17 are variants of the lower electrode according to the first exemplary embodiment of the present invention;

FIG. 18 is a cross-sectional view of a plasma processing apparatus according to a second exemplary embodiment of the present invention; and

FIGS. 19 and 20 are cross-sectional views illustrating an operation of the plasma processing apparatus according to the second exemplary embodiment of the present invention.

### DESCRIPTION OF THE PREFERRED EMBODIMENTS

Preferred embodiments of the invention are described hereafter in detail with reference to accompanying drawings. The present invention, however, is not limited to the embodiments described herein, but may be modified in a variety of ways, and the embodiments is provided only to fully describe the invention and inform those skilled in the art of the aspects of the invention. The same reference numeral indicates the same components in the drawings.

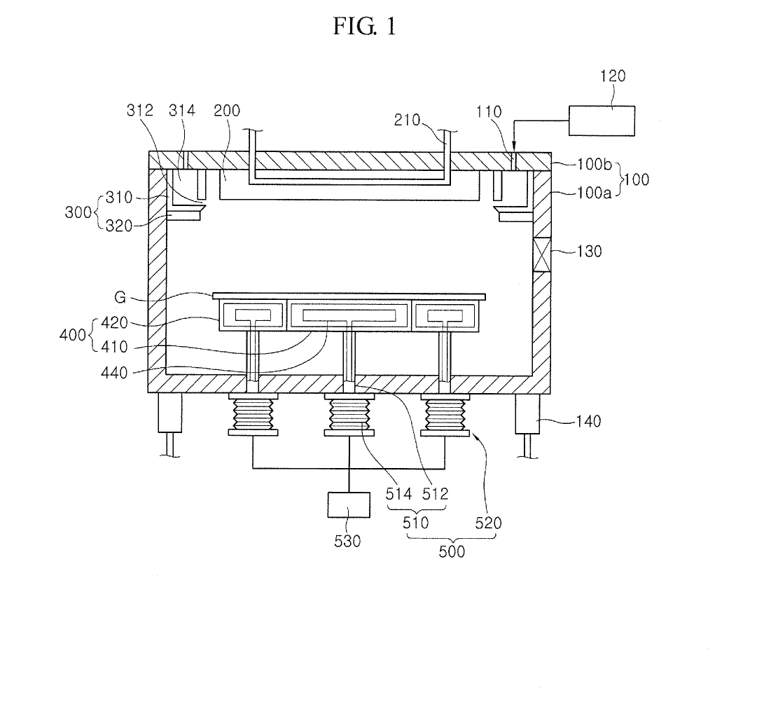

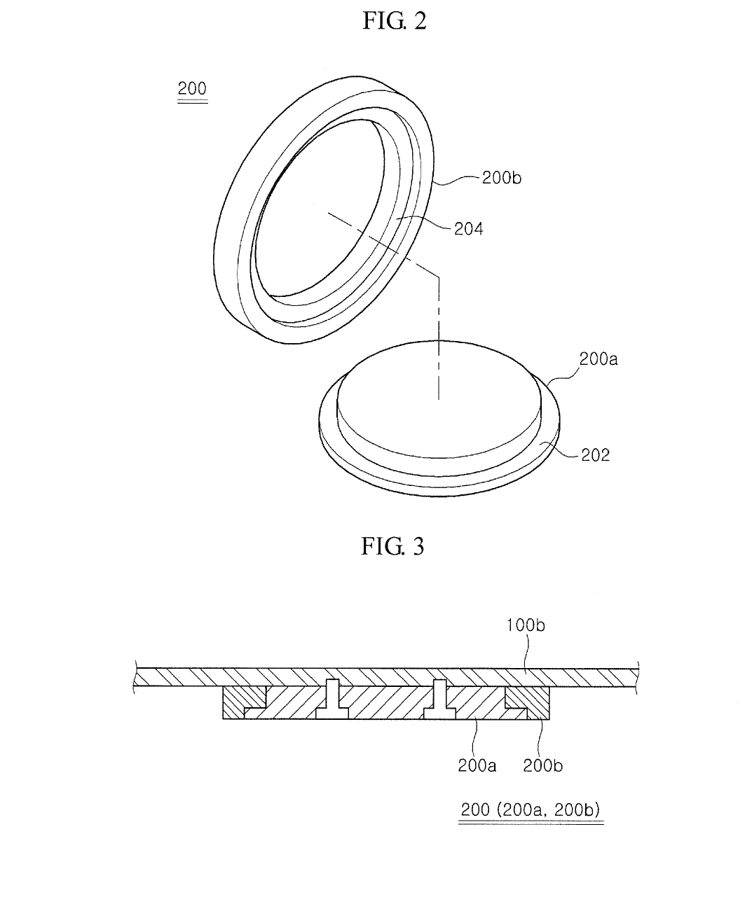

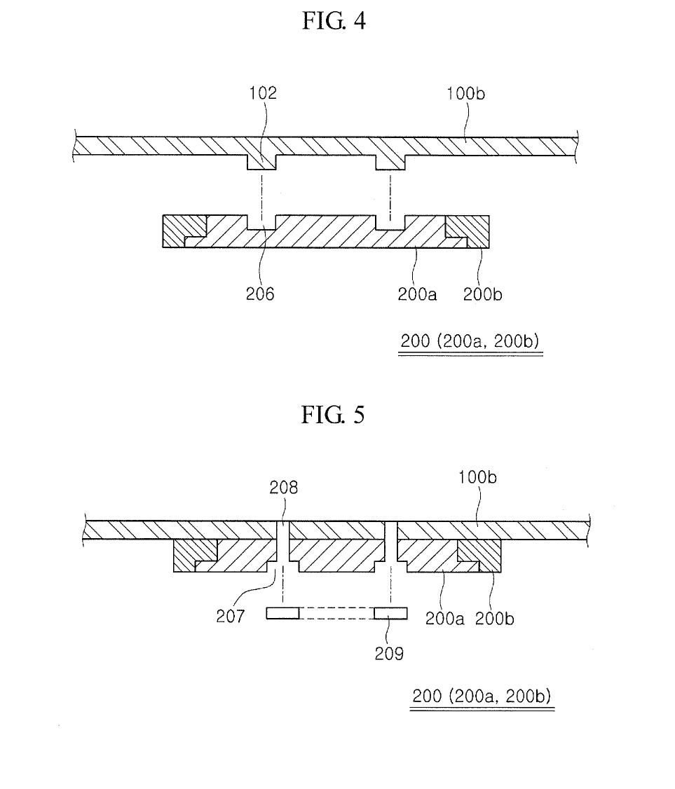

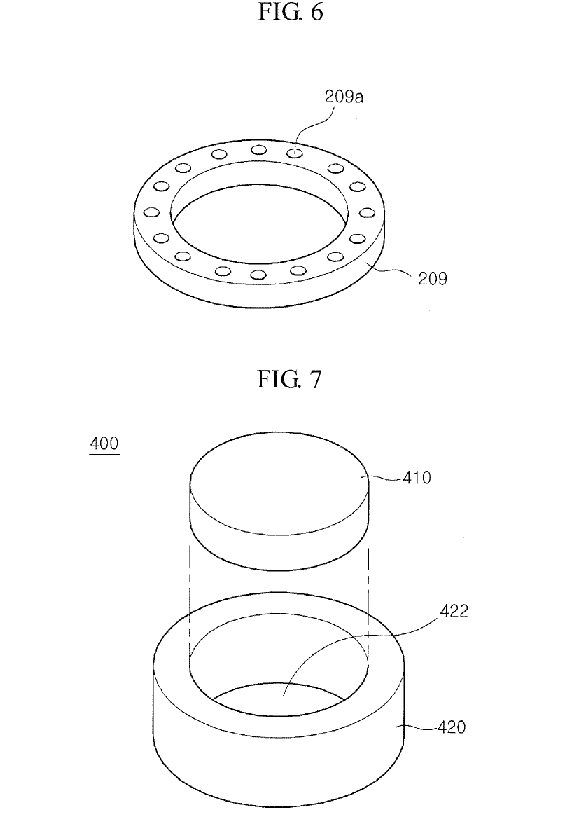

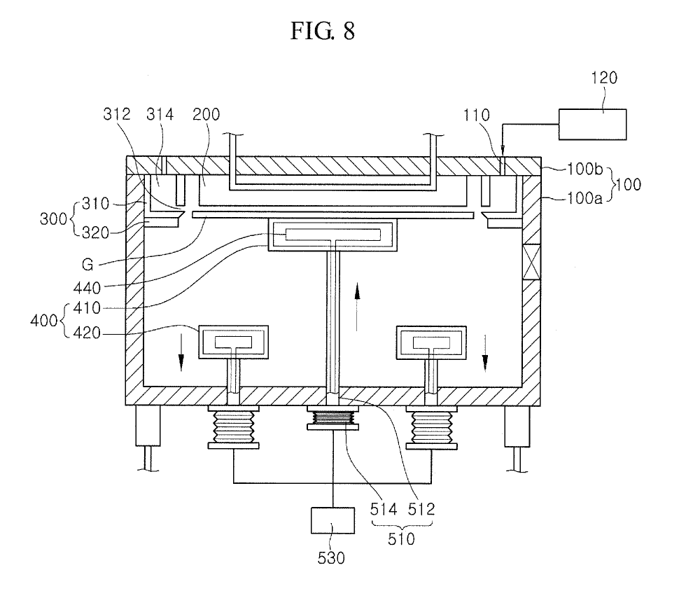

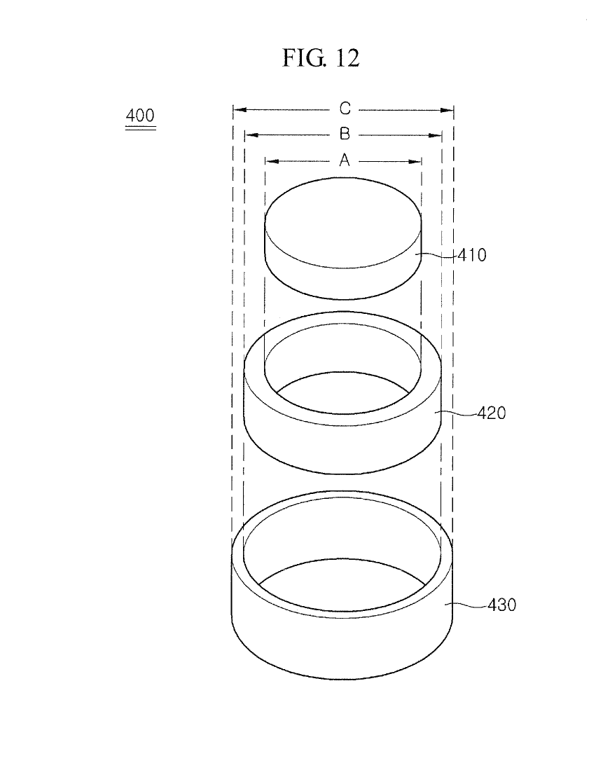

FIG. 1 is a cross-sectional view of a plasma processing apparatus according to a first exemplary embodiment of the present invention. FIG. 2 is a perspective view showing a variant of an insulating member provided in the plasma processing apparatus according to the first exemplary embodiment of the present invention. FIG. 3 is a cross-sectional view showing the insulating member of FIG. 2 attached to a chamber. FIG. 4 is a cross-sectional view of a first variant of the insulating member provided in the plasma processing apparatus according to the first exemplary embodiment of the present invention. FIG. 5 is a cross-sectional view of a second variant of the insulating member provided in the plasma processing apparatus according to the first exemplary embodiment of the present invention. FIG. 6 is a rear perspective view of a gas injector ring shown in FIG. 5. FIG. 7 is an exploded perspective view of a lower electrode according to the first exemplary embodiment of the present invention. FIGS. 8 to 11 are schematic cross-sectional views illustrating a process of removing impurities on a side and a lower surface of a substrate. FIGS. 12 to 17 are variants of the lower electrode according to the first exemplary embodiment of the present invention.

Referring to FIG. 1, a plasma processing apparatus using reactive ion etching (“RIE”) according to an exemplary embodiment of the present invention includes: a chamber 100; an insulating member 200 disposed at an upper portion inside the chamber 100; a ground electrode 300 provided at an upper portion of a side wall of the chamber 100; a lower electrode 400 on which a substrate G is placed; and a lift member 500 for moving up/down the lower electrode 400.

The chamber 100 is made of aluminum of which surface is anodized. The chamber 100 includes a lower chamber 100a and a chamber lid 100b covering the upper portion of the lower chamber 100a. The lower chamber 100a is formed in a cylindrical shape with a top open. The shape of the lower chamber 100a may be changed according to a shape of a semiconductor wafer or a glass substrate. The chamber lid 100b closes the upper portion of the lower chamber 100a and hermetically contacts with the upper portion of the lower chamber 100a to form a predetermined space inside the chamber 100.

A gas supply channel 110 is formed at the upper portion of the chamber 100. The gas supply channel 110 passes through the upper wall of the chamber 100 to feed a reactive gas, and is connected to a gas supplier 120. Therefore, a reactive gas is supplied into the chamber 100 through the gas supply channel 110 from the gas supplier 120. The reactive gas may be one of Ar, CF₄, Cl₂, SF₆, BCl₃ and combinations thereof. A gate 130 through which the substrate G is loaded into the chamber 100 is formed at a side wall of the chamber 100. The gate 130 opens/closes to load or unload the substrate G into or from the chamber 100. In the above, one gate 130 is formed at the side wall of the chamber 100. However, another gate may be formed at the other side wall facing the gate 130 of the chamber 100. That is, the substrate G may be inserted through a gate before a process and may be unloaded through the other gate after the process. Exhaust pipes 140 are provided at a bottom of the chamber 100. Reaction by-products, such as particles generated during etching, and gases are exhausted outside the chamber through the exhaust pipes 140. The exhaust pipes 140 may be formed at the lower portions of the side walls of the chamber 100, as well as the bottom of the chamber 100.

The insulating member 200 is disposed in an upper portion of the chamber 100, i.e. on the lower surface of the chamber lid 100b to have a circular plate shape. The insulating member 200 uniformly distributes the plasma generated around the substrate G in the chamber 100, and protects upper inner walls of the chamber 100. A cooling line 210 is provided inside the insulating member 200 to regulate a temperature of the insulating member 200, and connected to a cooling water supplier (not shown). Therefore, cooling water is supplied from the cooling water supplier to the cooling line 210. The cooling water prevents the insulating member 200 from being damaged by the plasma generated in the chamber 100. A coating material, for example Y₂O₃, is coated on an edge area of a lower surface and a side wall of the insulating member 200 to prevent particles generated in the chamber 100 from attaching to the edge and side wall.

The insulating member 200 is formed as a single plate shape in the above configuration, but the present invention is not limited thereto. The insulating member 200 may be divided into a plurality of insulating members. Referring to FIGS. 2 and 3, the insulating member 200 may include an inner insulating member 200a and an outer insulating member 200b which is coupled to an outer circumference of the inner insulating member 200a.

The inner insulating member 200a is formed in a circular plate shape. A first step 202 having an L-shaped cross-section is formed around the circumference of the inner insulating member 200a. The outer insulating member 200b is formed in a ring shape having a through hole at the center. A second step 204 having an inverse L-shaped cross-section is formed along an inside edge of the outer insulating member 200b to correspond to the first step 202 which is formed around the circumference of the inner insulating member 200a. The outer insulating member 200b is assembled with the inner insulating member 200a from above. In detail, the second step 204 of the outer insulating member 200b is placed on the first step 202 of the inner insulating member 200a, such that the inner insulating member 200a supports the outer insulating member 200b. The inner insulating member 200a supporting the outer insulating member 200b is fastened to the lower surface of the chamber lid 100b by fastening members, such as bolts. As such, the insulating member 200 is fixed to the lower surface of the chamber lid 100b. The shapes of the first step 202 and the second step 204 are not limited to the above shapes and may be changed into any shapes as long as the outside of the inner insulating member 200a can be completely coupled to the inside of the outer insulating member 200b.

According to the above configuration, a coating material is coated only on the lower surface and the side of the outer insulating member 200b for insulation and preventing attachment of particles, thereby manufacturing cost can be reduced as compared to the conventional insulating member of which entire surface is coated with the coating material. Further, a various outer insulating members 200b having different sizes can be replaced depending on a size of the insulating member 200 to be installed inside the chamber 100.

The insulating member 200 may have the following configuration such that it is attached always to the same position of the lower surface of the chamber lid 100b. As shown in FIG. 4, a predetermined groove 206 is formed on the upper surface of the inner insulating member 200a, and a protrusion 102 corresponding to the groove is protruded from the lower surface of the chamber lid 100b. The groove 206 and the protrusion 102 are formed to have a shape of a looped curve. The groove 206 of the inner insulating member 200a supporting the outer insulating member 200b is coupled to the protrusion 102 protruding from the lower surface of the chamber lid 100b. The inner insulating member 200a is then fastened to the lower surface of the chamber lid 100b by fastening members, such as bolts. According to the above configuration, the insulating member 200 is fixed always at the same position on the lower surface of the chamber lid 100b, such that arrangement time can be saved.

In the above configuration, the groove 206 and protrusion 102 are respectively formed on the insulating member 200 and the chamber lid 100b to have a shape of the looped curve. However, the present invention is not limited thereto. That is, pluralities of protrusions 102 and corresponding grooves 206 may be separately formed and arranged so that the general shape appears as the looped curve. Further, pluralities of protrusions and corresponding grooves may be formed along the looped curve. Furthermore, although the groove 206 is formed on the inner insulating member 200a and the protrusion 102 is formed on the lower surface of the chamber lid 100b, the protrusion may be formed on the inner insulating member 200a and the predetermined groove may be formed on the lower surface of the chamber lid 100b. In addition, although the protrusion 102 is formed on the lower surface of the chamber lid 100b in the above configuration, it is possible to insert an aluminum plate (not shown) between the chamber lid 100b and the insulating member 200 and form a protrusion on the lower surface of the plate to assemble them.

The insulating member may have the following configuration to reduce the temperature of the upper surface of the substrate during a process. As shown in FIGS. 5 and 6, the inner insulating member 200a is formed in a circular plate shape and a gas injector ring 209 is disposed on the lower surface of the inner insulating member 200a. Further, the outer insulating member 200b is coupled to the outside of the inner insulating member 200a. The inner insulating member 200a and outer insulating member 200b assembled as described above are then attached to the lower surface of the chamber lid 100b.

A lower groove 207 having a shape of looped circle is formed on the lower surface of the inner insulating member 200a. A gas line 208 is formed through the inner insulating member 200a to communicate with the lower groove 207. The gas line 208 is formed through the chamber lid 100b to communicate with the chamber lid 100b to which the inner insulating member 200a is attached. A cooling gas, such as helium, may be supplied through the gas line 208. The gas injector ring 209 is fitted into the lower groove 207 on the lower surface of the inner insulating member 200a. The gas injector ring 209 is formed in a ring shape with the center cut vertically, and includes a plurality of injection holes 209a formed along the lower surface. The plurality of injection holes 209a may communicate with the gas line 208 of the inner insulating member 200a. Further, the shape of the injection hole 209a is not limited and may be a circle, a polygon or the like.

When plasma is generated around the lower surface of the substrate after the process starts, the cooling gas is injected to the upper surface of the substrate through the chamber lid 100b and the inner insulating member 200a. In this way, increase of a substrate temperature by the plasma can be prevented.

According to the above configuration, it is possible to prevent a deformation of the substrate caused by the increased temperature of the edge area of the substrate due to the plasma during the process of the substrate. Although the insulating member is cooled by the cooling line, cooling is less effective in vacuum environment because there is no heat conducting medium between the substrate and the insulating member. Therefore, the substrate temperature can be regulated more effectively by such a configuration of the insulating member.

Returning to FIG. 1, the ground electrode 300 is provided to the upper portion of the side wall of the chamber 100, and formed in a ring shape. The ground electrode 300 includes an inner electrode 310 and an outer electrode 320, each of which is grounded.

The upper portion of the inner electrode 310 is connected to the gas supply channel 110 formed through the upper wall of the chamber 100. And a predetermined space 314 is formed inside the inner electrode 310. Further, a plurality of gas injection nozzles 312 is formed at a side of a sidewall of the inner electrode 310 to be connected to the predetermined space 314. The reactive gas is supplied into the predetermined space 314 formed inside the inner electrode 310 through the gas supply channel 110 formed through the upper wall of the chamber 100. The reactive gas supplied to the space 314 introduced to the chamber 100 through the gas injection nozzle 312 formed at the side wall of the inner electrode 310. The outer electrode 320 is formed at an upper portion of a sidewall of the chamber 100, more particularly adjacent to the lower surface of the inner electrode 310.

With start of the process, the edge area of the substrate G, in detail, the edge area of the upper surface, the side, and the edge area of the lower surface of the substrate is disposed adjacent to the electrodes 300. That is, the inner electrodes 310 and the outer electrodes 320 of the electrode 300 are disposed adjacent to the edge area of the substrate G to etch away particles and thin films accumulated at the edge area of the upper surface, the side, and the edge area of the lower surface of the substrate G using the plasma. The inner electrode 310 and the outer electrode 320 may be formed as a single electrode, and a dielectric film may be formed on the surface of the inner electrode 310 and the outer electrode 320 to protect the electrodes 310, 320.

The lower electrode 400 is provided in a lower portion inside the chamber 100. The lower electrode 400 includes a first electrode 410 and a second electrode 420 surrounding the first electrode 410. Further, the lower electrode 400 is connected to an RF power supply (not shown) for supplying power to the lower electrode 400. _In addition, an RF matching device (not shown) may be further provided between the lower electrode 400 and the RF power supply. The RF matching device detects impedance in the chamber 100, and generates an imaginary component having an opposite phase to the detected imaginary component, so that the resultant impedance is the same as a real component of the impedance. The RF matching device then supplies a maximum power and thereby generates optimum plasma in the chamber 100. The lower electrode 400 may be formed in a circular or polygonal shape, particularly depending on the substrate G formed of a semiconductor wafer or a glass substrate for a flat panel display. The lower electrode 400 will be described below in detail with reference to the accompanying drawings.

A chuck (not shown) for supporting the substrate G may be further provided on the first electrode 410 and the second electrode 420. The chuck may be an electrostatic chuck using static electricity, but is not limited thereto. The chuck may suck and support the substrate G using a vacuum force or a mechanical force. Further, a cooling line 440 and a cooling water supplier (not shown) which is connected to the cooling lines may be further provided in the first electrode 410 and the second electrode 420 to regulate temperature of the first and second electrodes 410 and 420. Further, a helium line (not shown) may be further provided through the first electrode 410 and the second electrode 420. Helium is supplied through the helium line and regulates temperature of the substrate G.

The lift member 500 includes a first lower lift 510 and a second lower lift 520, and is connected to the lower electrode 400. The first lower lift 510 is connected to the first electrode 410 and the second lower lift 520 is connected to the second electrode 420.

Each of the first lower lift 510 and the second lower lift 520 includes a support 512 and a bellows 514 connected to the support. The first lower lift 510 and the second lower lift 520 form one lift assembly. A stepping motor 530 is connected to the lift assembly and the first lower lift 510 and the second lower lift 520 are moved up and down by the stepping motor 530. In detail, as the first lower lift 510 moves up, the second lower lift 520 moves down; in contrast, as the second lower lift 520 moves up, the first lower lift 510 moves down, which is similar to a seesaw. The first lower lift 510 and the second lower lift 520 are simultaneously controlled as one lift assembly in the above configuration. But the first lower lift 510 and the second lower lift 520 may be separately controlled.

The lift member 500 is not limited to the above configuration according to the exemplary embodiment of the present invention, but may be any members capable of moving lower electrode 400 up and down. That is, a cylinder using hydraulic pressure or air pressure, or an linear motor (LM) guide may be used. Further, a combination of the foregoing may be used.

On the other hand, as shown in FIG. 7, a lower electrode 400 according to the exemplary embodiment of the present invention includes an inner electrode of a circular plate shape (hereinafter, referred to as a “first electrode”, 410) and a ring-shaped outer electrode (hereinafter, referred to as a “second electrode”, 420). The first and second electrodes 410 and 420 are coaxially arranged. The inner circumference of the second electrode 420 is spaced apart from the outer circumference of the first electrode 410 by a predetermined distance. The first electrode 410 is formed in a circular plate shape and the second electrode 420 is formed in a ring shape with an opening 422 at the center. The first electrode 410 moves up and down through the opening 422 of the second electrode 420. It is desirable that the outside of the first electrode 410 doesn't interfere with the inside of the second electrode 420. The distance between the outside of the first electrode 410 and the inside of the second electrode 420 may be in a range of 0.1 mm to 10 mm.

A process of removing particles and thin films accumulated on the edge area of the upper surface, the side, the edge area of the lower surface, and the central portion of the substrate in accordance with the operation of the above configuration is described hereafter with reference to FIGS. 8 to 11.

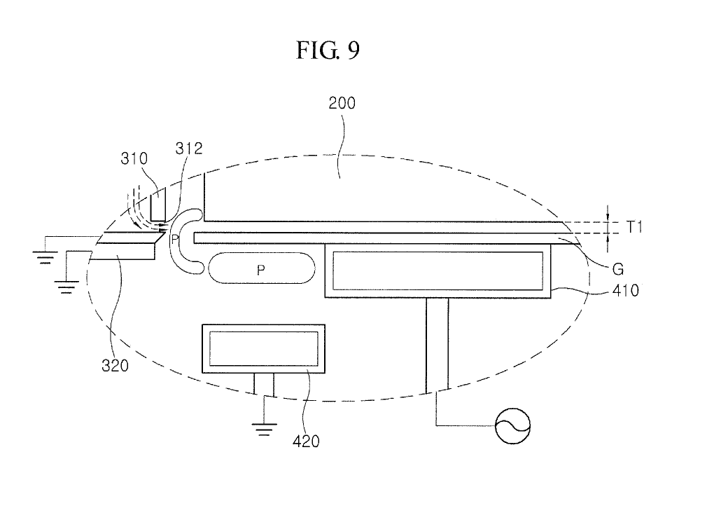

As shown in FIG. 8, while the substrate G is placed on the first electrode 410, the first lower lift 510 connected to the lower portion of the first electrode 410 is moved up by the stepping motor 530 until the first electrode 410 is spaced apart from the insulating member 200 in the upper portion of the chamber 100 by a predetermined distance. A reactive gas is supplied into the space 314 of the inner electrode 310 through the gas supply channel 110 formed in the chamber lid 100b from the gas supplier 120, and then, as shown in FIG. 9, flows into the chamber 110 through the gas injection nozzles 312 at a side of the inner electrode 310. A ground potential is applied to the inner electrode 310, the outer electrode 320, and the second electrode 420 and an RF is applied to the first electrode 410, such that plasma P is generated in the chamber 10.

The plasma P is generated in a space surrounded by the first electrode 410, the inner electrode 310 where the ground potential is applied, outer electrode 320, and second electrode 420, in detail, around the edge area of the upper surface, the side, and the edge area of the lower surface of the substrate G. Because the distance T1 between the insulating member 200 and central portion of the upper surface of the substrate G is maintained at 1 mm or less, the plasma P is not generated therebetween. Therefore, the plasma P generated as described above removes particles and thin films accumulated on edge area of the upper surface, the side, and the edge area of the lower surface of the substrate G.

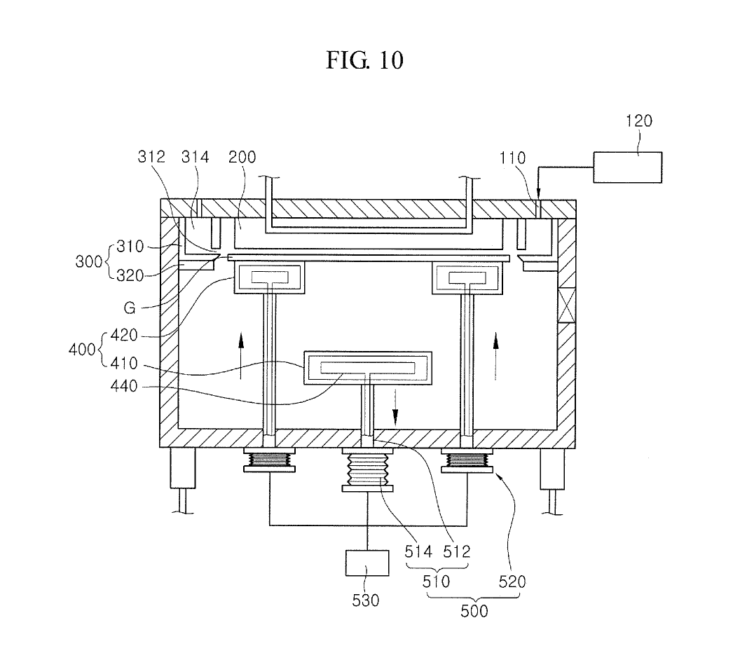

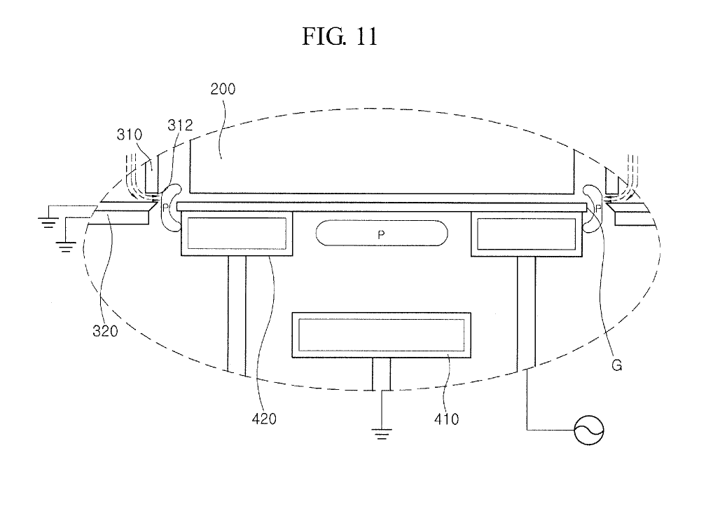

As shown in FIG. 10, while the substrate G is placed on the first electrode 410, the first lower lift 510 connected to the lower portion of the first electrode 410 moves down by the stepping motor 530, and the second lower lift 520 connected to the second electrode 420 moves up. The edge area of the lower surface of the substrate G is then placed on the second electrode 420 moving up. The second electrode 420 stops at a predetermined distance from the insulating member 200 in the upper portion of the chamber 100. A reactive gas flows into the space 314 of the inner electrode through the gas supply channel 110 formed in the chamber lid 110b from the gas supplier 120 connected to the upper portion of the chamber 100. The reactive gas then flows into the chamber 100 through the gas injection nozzle 312 at a side of the inner electrode 310 as shown in FIG. 11. A ground potential is applied to the inner electrode 310, the outer electrode 320, and the first electrode 410, and an RF is applied to the second electrode 420, such that plasma P is generated.

The plasma P is generated in a space surrounded by the second electrode 420 where the RF is applied, the inner electrode 310 where the ground potential is applied, outer electrode 320, and first electrode 410, in detail, around the edge area of the upper surface, the side, and the central portion of the lower surface of the substrate G. Because the distance between the insulating member and the central region of the upper surface of the substrate is maintained at 1 mm or less, the plasma P is not generated. Therefore, the plasma P generated as described above removes particles and thin films accumulated on the edge area of the upper surface, the side, and the central portion of the lower surface of the substrate G.

Because the first electrode 410 has a smaller area than a conventional lower electrode, a separate lift member is not needed. The conventional lower electrode is provided with a separate lift member for supporting a substrate. That is, when the substrate is inserted into the chamber by an outer robot arm, a lift pin which is provided in the lower electrode moves up, and the substrate is placed on the lift pin. The substrate on the lift pin is then placed on the lower electrode as the lift pin moves down. On the contrary, according to the exemplary embodiment of the invention, when the substrate G is inserted into the chamber 100 by an outer robot arm (not shown), the first electrode 410 can support the lower portion of the substrate G without interference of the robot arm. Therefore, the substrate G can be placed on the first electrode 410 without the separate lift pin according to the exemplary embodiment of the present invention.

Although the lower electrode 400 includes the first electrode 410 and the second electrode 420 in the above configuration, the present invention is not limited thereto. That is, an intermediate electrode may be further provided between the inner electrode and the outer electrode located at the outermost region.

As shown in FIG. 12, a lower electrode 400 includes an inner electrode of a circular plate shape (hereinafter, referred to as a “first electrode”, 410), a ring-shaped intermediate electrode (hereinafter, referred to as a “second electrode”, 420) and a ring-shaped outer electrode (hereinafter, referred to as a “third electrode”, 430). Each of the electrodes is coaxially arranged. The inner circumference of the second electrode is spaced apart from the outer circumference of the first electrode 410 by a predetermined distance. The inner circumference of the third electrode is spaced apart from the outer circumference of the second electrode 420 by a predetermined distance.

The outer circumference of the first electrode 410 is disposed at a predetermined distance from the inner circumference of the second electrode 420. The outer circumference of the second electrode 420 is disposed at a predetermined distance from the inner circumference of the third electrode 430.

After a substrate is placed on the first electrode 410 and the reactive gas flows into the chamber through the inner electrode, the first electrode 140 moves up to be spaced apart by a predetermined distance from the insulating member in the upper portion of the chamber. An RF is applied to the first electrode 410, and a ground potential is applied to the inner electrode, outer electrode, second electrode 420, and third electrode 430. Therefore, plasma is generated between the first electrode 410 and the ground potential, i.e. around the edge area of the upper surface, the side, and the edge area of the lower surface of the substrate G, such that particles and thin films accumulated thereon are removed by the plasma.

Likewise, the second electrode 420 moves up and stops at a predetermined distance from the insulating member. The RF is applied to the second electrode 420 and the ground potential is applied to the inner electrode, outer electrode, first electrode 410, and third electrode 430. Therefore, plasma is generated between the second electrode 420 and the ground electrode, such that particles and thin films accumulated on the edge area of the upper surface, the side, and the lower surface of the substrate are removed by the plasma.

Similarly, the third electrode 430 moves up and stops at a predetermined distance from the insulating member. The RF is applied to the third electrode 430 and the ground potential is applied to the inner electrode, outer electrode, first electrode 410, and second electrode 420. Therefore, plasma is generated between the third electrode 430 and the ground potential, such that the particles and thin films accumulated on the edge area of the upper surface, the side, and the central portion of the lower surface of the substrate G are removed by the plasma.

According to the above configuration, as the first electrode 410 moves up, the second and third electrodes 420 430 move down; as the second electrode 420 moves up, the first and third electrodes 410 and 430 move down; and as the third electrode 430 move up, the first and second electrodes 410 and 420 moves down. However, the present invention is not limited thereto. That is, the second electrode 420 may move down while the first and third electrodes 410 and 430 move up; and as the second electrode 420 move up, the first electrode 410 and the third electrode 430 moves down. Further, depending on processes, the first to third electrodes 410, 420 and 430 may move up and down individually or in combination with one another.

A diameter B of the second electrode may be in a range of 56% to 70% of a diameter C of the third electrode. A diameter A of the first electrode may be in a range of 49% to 56% of the diameter C of the third electrode. Further, the distances between the first electrode 410 and the second electrode 420; and between the second electrode 420 and the third electrode 430 may be in a range of 0.1 mm to 10 mm to avoid interference between boundaries while the respective electrodes are moving up and down. Therefore, the diameters A, B and C of the first to third electrodes may be changed appropriately.

For example, for a substrate having a diameter of 300 mm, the diameter C of the third electrode may be formed to be the same as or less than that of the substrate, i.e., 300 mm or less. The diameter B of the second electrode is formed to be in a range of 56% to 70% of the diameter C of the third electrode, i.e., 170 mm to 210 mm. The diameter A of the first electrode is formed to be in a range of 49% to 56% of the diameter C of the third electrode, i.e., 120 mm to 170 mm. Particles and thin films accumulated on the edge area of the upper surface, the side, and the central portion of the lower surface of the substrate can be removed without deformation of the substrate, when the substrate having a diameter of 300 mm is processed using the first to third electrodes 410,420 and 430, wherein the second electrode 420 moves down while the first and third electrodes 410 and 430 move up; the first and third electrodes 410 and 430 move down while the second electrode 420 moves up; and the first to third electrodes have appropriate diameters in a range described above. In particular, in an experiment where the diameter C of the third electrode is fixed at 300 mm or less; and the diameters A and B of the first and second electrodes are formed to be out of the range described above, it was found that the central portion of the substrate deforms upward in all the cases. Therefore, when a substrate having a diameter of 300 mm is processed by a plasma processing apparatus including the first to third electrodes 410, 420 and 430, it can be seen that the diameters A, B and C of the first to third electrodes are important factors.

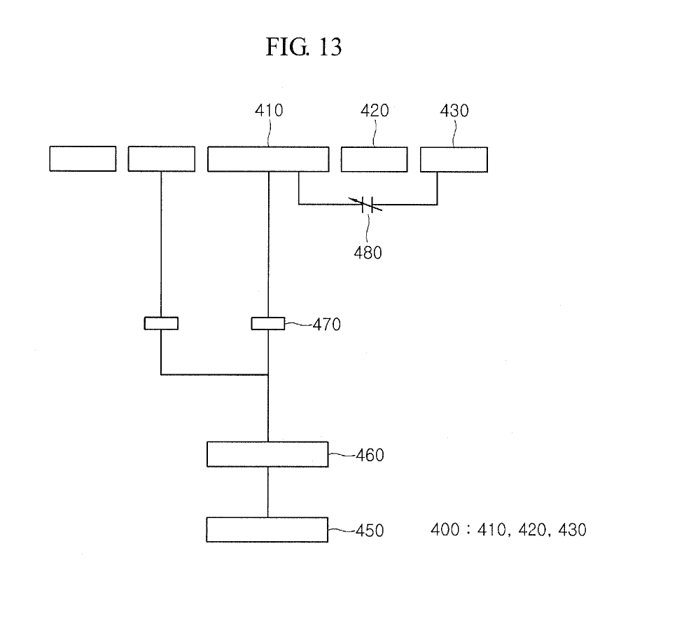

Further, power may be applied to the electrodes as follows. As shown in FIG. 13, the first to third electrodes 410, 420 and 430 are coaxially spaced apart from each other by predetermined distances, and a power distributor 480 is provided between the first electrode 410 and the third electrode 430. An RF power supply 450 and an RF matching device 460 are connected to the lower portions of the first electrode 410 and the second electrode 420. Furthermore, sensors 470 are provided between the RF matching device 460 and the first electrode 410, and between the RF matching device 460 and the second electrode 420.

The power distributor 480 is connected between the first electrode 410 and the third electrode 430. The power distributor 480 attenuates the power applied to the first electrode 410, i.e. the power applied to the first electrode 410 when a high-frequency power is applied to the third electrode 430. The power distributor 480, for example, may use a variable condenser or resistance etc., and preferably a variable condenser. Although the power distributor 480 attenuates the power applied to the first electrode 410 and then applies the power to the third electrode 430, the present invention is not limited thereto. The power distributor may amplify the power applied to the first electrode 410 and then apply the power to the third electrode 430. The above power distributor 480 can appropriately control plasma generated around a substrate G by regulating the high-frequency power that is applied to the first electrode 410 and the third electrode 430. Therefore, deformation of the substrate G can be prevented during the process and etching uniformity around the edge area and the central portion of the lower surface of the substrate is increased.

The sensors 470 are provided between the first electrode 410 and the RF matching device 460, and between the second electrode 420 and the RF matching device 460. The sensor 470 detects the amount of power that is supplied from the RF power supply and then distributed to the first electrode 410 and the second electrode 420. The detected power is monitored and compared by an external device.

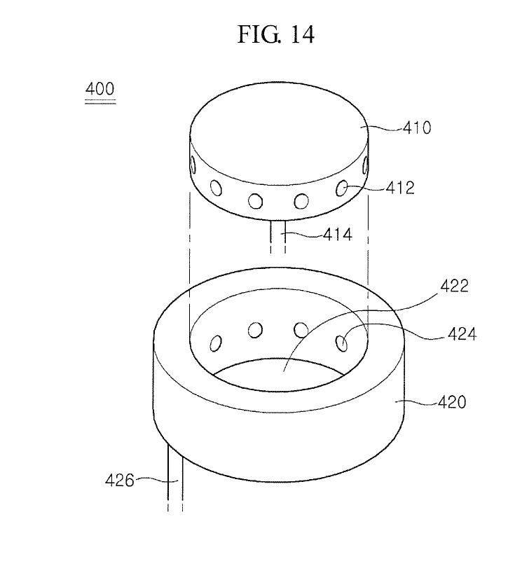

Further, gas injection holes may be formed in a plurality of electrodes to feed a reactive gas into the chamber, of which configuration is as follows. As shown in FIG. 14, a lower electrode 400 includes a first electrode 410 and a second electrode 420 that is coaxially disposed by a predetermined distance from the first electrode 410.

The first electrode 410 is formed in a circular plate shape, and a plurality of first gas injection holes 412 is formed along the outer circumference of the first electrode 410. Further, a first gas supply line 414 is connected to the lower portion of the first electrode 410. A predetermined space (not shown) is formed in the first electrode 410, and the plurality of first gas injection holes 412 are formed along the outer circumference of the first electrode 410 to communicate with the predetermined space. The first gas supply line 414 also communicates with the predetermined space in the first electrode 410. Therefore, a reactive gas supplied through the first gas supply line 414 passes through the predetermined space in the first electrode 410 and then injected into the chamber through the first gas injection holes 412 formed along the outer circumference of the first electrode 410. The second electrode 420 is formed in a ring shape so that the inner circumference is spaced apart from the outer circumference of the first electrode 410 by a predetermined distance. The first and second electrodes 410 and 420 are coaxially arranged. A plurality of gas injection holes 424 is formed along the inner circumference of the second electrode 420. Further, a second gas supply line 426 is connected to the lower portion of the second electrode 420. Similar to the first electrode 410, a predetermined space (not shown) communicating with the second gas injection holes 424 is formed in the second electrode 420. The predetermined space communicates with the second gas supply line. Therefore, the reactive gas supplied through the second gas supply line 426 passes through the space in the ring-shaped second electrode 420 and then is injected into the chamber through the second gas injection holes 424.

When the substrate is placed on the first electrode 410 and then spaced apart from an insulating member in the upper portion of a chamber by a predetermined distance, the reactive gas is uniformly injected through the first gas injection holes 412 formed along the outer circumference of the first electrode 410. The injected reactive gas is uniformly distributed along the edge area of the lower surface of the substrate, such that plasma can be uniformly generated. Meanwhile, when the substrate is placed on the second electrode 420 and then spaced apart from the insulating member in the upper portion of the chamber, the reactive gas is uniformly injected through the second gas injection holes 424 formed along the inner circumference of the second electrode 420. The injected reactive gas is uniformly distributed around the central region of the lower surface of the substrate G, such that plasma can be uniformly generated. Density of the plasma can be controlled by regulating the amount of reactive gas injected through the first and second gas injection holes 412 and 424. Therefore, the accumulated particles and thin films can be removed more effectively.

The first and second gas injection holes 412 and 424 may be connected to one gas supply line or respective gas supply lines. A heating member (not shown), for example a heater, for heating the first and second electrodes 410 and 420 may be further provided in the first and second electrodes 410 and 420.

In the above configuration, the reactive gas is supplied to the first and second electrodes 410 and 420 in the lower portion of the chamber, and thereby particles and thin films accumulated on the lower surface of the substrate can be effectively removed at any positions in the chamber irrespective of a position of the substrate G.

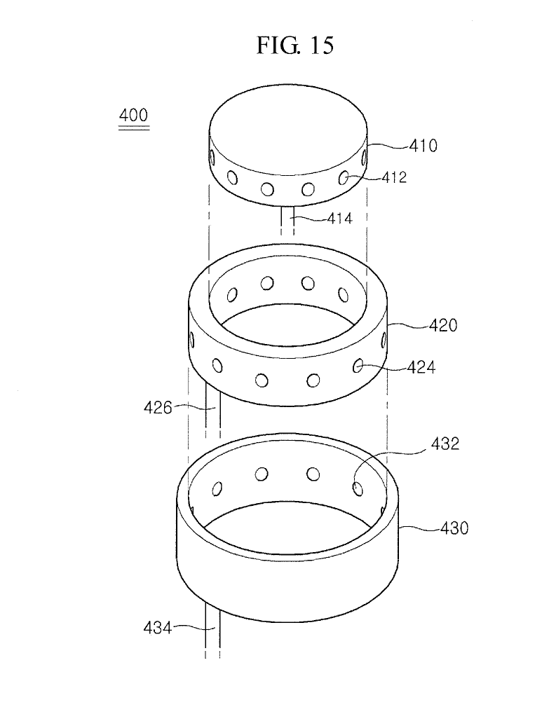

When the lower electrode includes at least three electrodes, they may be configured as follows. As shown in FIG. 15, a lower electrode 400 is formed to have a circular plate shape and includes a first electrode 410, a second electrode 420 and a third electrode 430. The first electrode is provided with first gas injection holes 412 along an outer circumference thereof. The second electrode 420 is formed to have a ring shape and coaxially disposed at a predetermined distance from the outer circumference of the first electrode 410. Second gas injection holes 424 are formed along the inner and outer circumferences of the second electrode 420. The third electrode 430 is formed to have a ring shape and coaxially disposed at a predetermined distance from the outer circumference of the second electrode 420. Third gas injection holes 432 are formed along the inner circumference of the third electrode 420. Configurations of the first and third electrodes 410 and 430 are the same as that shown in FIG. 11 and the corresponding description will be omitted.

The second electrode 420 is formed in a ring shape with a center cut vertically. The inner diameter is determined such that the first electrode 410 can be inserted, and the outer diameter is determined such that the second electrode 420 can be inserted into the third electrode 430. The second gas injection holes 424 are formed along the inner and outer circumference of the second electrode 420 to communicate with each other. A gas supply line 426 is connected to the lower portion of the second electrode 420 to communicate with the second gas injection holes 424. The second gas injection holes 424 are formed along the inner and outer circumference of the second electrode 420 such that they are connected with each other in the above configuration, but the gas injection holes may be independently formed.

When a substrate is placed on the second electrode 420 and then disposed at a predetermined distance from an insulating member in the upper portion of a chamber, the reactive gas is injected along the inner and outer circumference of the second electrode through the second gas injection holes 424. The injected reactive gas is uniformly distributed along the central portion of the lower surface and the edge area of the substrate. The uniformly distributed reactive gas generates uniform plasma, whereby particles and thin films accumulated on the edge and the center portions of the lower surface of the substrate can be effectively removed. Further, density of the plasma can be controlled by regulating the amount of the injected reactive gas.

The lower electrode 400 is divided into three electrodes in the above configuration, but the present invention is not limited thereto. The lower electrode 400 may be separated into a plurality of electrodes, i.e. four or more electrodes. When the lower electrode is separated into three or more electrodes, the innermost electrode may have gas injection holes only along the outer circumference thereof, and the outermost electrode may have gas injection holes only along the inner circumference thereof.

When the electrode is separated into a plurality of electrodes, the outermost electrode, i.e., the third electrode in this case may be configured as follows. Of course, the outermost electrode is not limited to the third electrode, and may be Nth electrode according to the number of electrodes. The third electrode is exemplified as the outermost electrode hereafter.

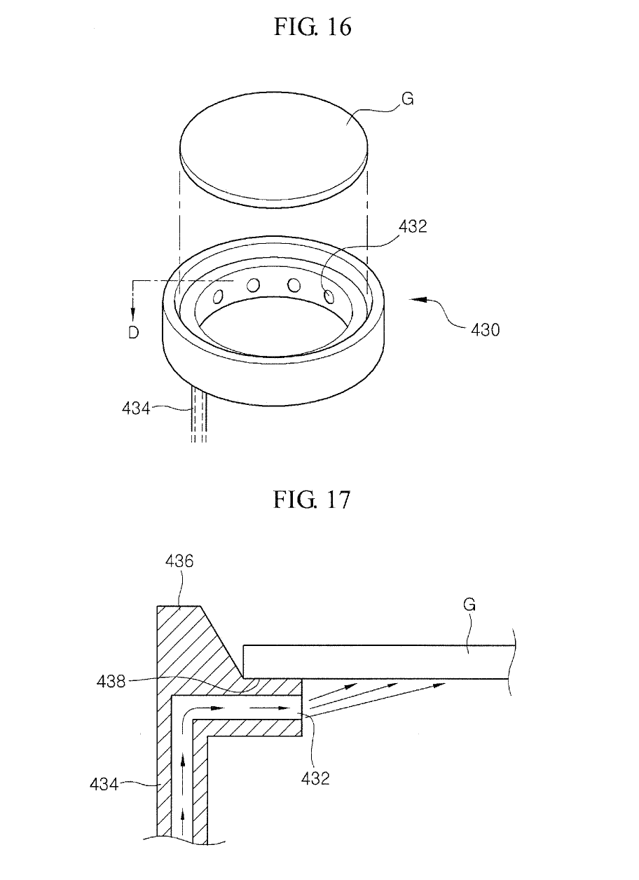

Referring to FIGS. 16 and 17, the third electrode 430 is formed in a ring shape having a through hole at the center thereof, and provided with third gas injection holes 432 along the inner circumference of the third electrode 430. A third gas supply line 434 is connected to the lower portion of the third electrode 430 to communicate with the third gas injection holes 432.

The diameter of the third electrode 430 is larger than that of the substrate G, and a seating portion is formed on the third electrode 430 to place the substrate G onto. In detail, the upper surface of the third electrode 430 includes a first plane 436 and a second plane 438. The second plane 438 is parallel to the first plane 436. The first and second planes 436 and 438 are connected by an inclined plane downwardly extending from the first plane. Therefore, the edge area of the lower surface of the substrate G is placed on the second plane 438, and the side of the substrate G faces the inclined plane between the first plane 436 and the second plane 438.

In the above configuration, the seating portion is formed in the third electrode 430 so that the substrate G can be place thereon. The seating portion prevents the substrate G from being separated from the third electrode 430 due to the injecting pressure of the reactive gas when the reactive gas is injected to the lower surface of the substrate G, the reactive gas being supplied through the third gas injection holes 432 formed in the third electrode 430.

In the above configuration, the first and second lower lifts 510 and 520 that are respectively connected to the first and second electrodes 410 and 420 are formed like a seesaw, and the first and second electrodes 410 and 420 alternately move up and down to remove particles and thin film accumulated on the substrate G. However, the first lower lift 510 may be connected to the first electrode 410 and an upper lift 600 may be connected to the insulating member 200 to remove particles attached and thin films accumulated on the substrate G.

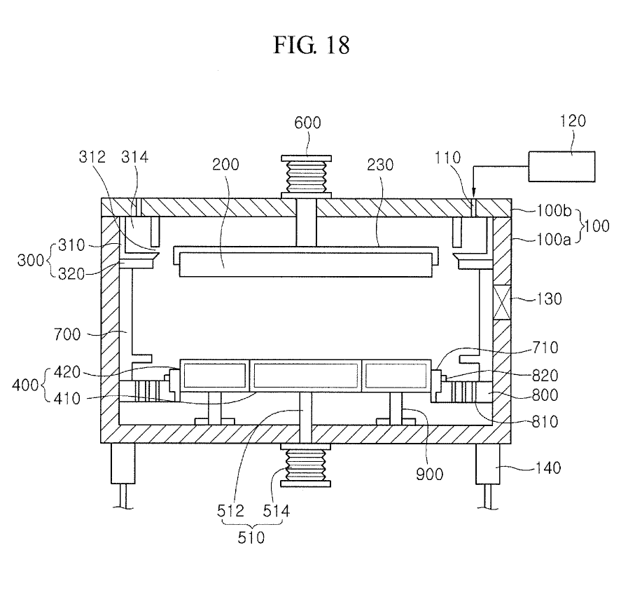

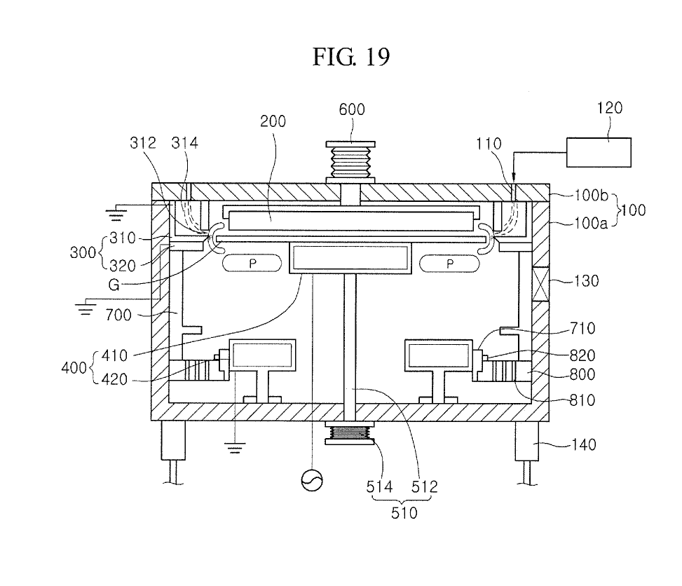

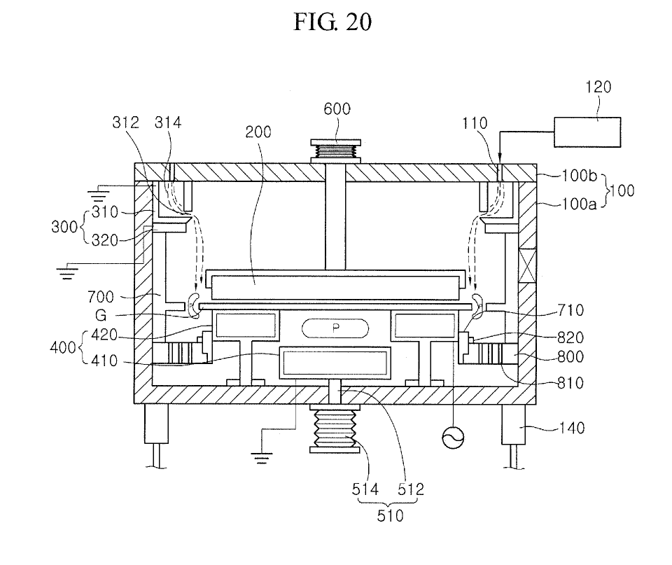

FIG. 18 is a cross-sectional view of a plasma processing apparatus according to a second exemplary embodiment of the present invention. FIGS. 19 and 20 are cross-sectional view illustrating an operation of the plasma processing apparatus according to the second exemplary embodiment of the present invention.

Referring to FIG. 18, a plasma processing apparatus includes a chamber 100; an insulating member 200 disposed in the upper portion of the chamber 100; a ground electrode 300 provided at the upper portion of the side wall of the chamber 100; a lower electrode 400 where a substrate G is placed; an upper lift member, i.e. an upper lift 600 and a first lower lift 510 for moving up and down the insulating member 200 and the lower electrode 400. The plasma processing apparatus further includes a chamber liner 700 provided at the inner wall of the chamber 100; a focus ring 710 disposed along the outer circumference of the lower electrode 400; a vent plate 800 disposed between the outer circumference of the lower electrode 400 and the inner wall of the chamber 100. Description on an overlapping configuration will be omitted.

The upper portion of the insulating member 200 is fixed by a support 230. The upper lift 600 is connected to the support 230 for moving the support 230 up and down. The upper lift 600 moves the insulating member 200 fixed to the support 230 to be spaced apart from the lower electrode 400 by a predetermined distance.

The first lower lift 510 is connected to the bottom of the first electrode 410 and moves the first electrode 410 up and down. An electrode support 900 connected to the floor of the chamber 100 is formed at the bottom of the second electrode. The second electrode 420 is spaced apart from the bottom of the chamber 100 by a predetermined distance by the electrode support 900.

The chamber liner 700 is formed along the inner wall of the chamber 100. The upper portion of the chamber liner 700 is electrically connected to the lower portion of the outer electrode 320. The chamber liner 700 protects the side wall of the chamber 100 from the plasma and a ground potential is applied to the chamber liner 700 similar to the outer electrode 320.

The focus ring 710 is formed in a ring shape along the outer circumference of the lower electrode 400. The focus ring 710 focuses plasma onto the substrate G when a reactive gas changes into the plasma.

The vent plate 800 is a circular plate of which center is bored and includes a through hole 810 vertically formed through the plate. The vent plate 800 is disposed between the lower electrode 400 and the inner wall of the chamber 100, and in detail, connects the outer circumference of the focus ring 710 to the inner wall of the chamber 100, whereby the inside of the chamber is divided into upper and lower portions. That is, the vent plate 800 controls pressure to uniformly distribute a reactive gas in the chamber 100, which generates uniform plasma. Therefore, local concentration of plasma in the chamber 100 can be prevented.

A protruding electrode 820 may be further provided on a side, i.e. the upper surface of the vent plate 800. The protruding electrode 820 makes a chamber pressure uniform and functions as an electrode by a ground electrode applied thereto. The protruding electrode 820 may be coupled with the vent plate 800 or integrally formed with the vent plate 800. The ground potential may be respectively applied to the vent plate 800 and the protruding electrode 820. The ground potential may be simultaneously applied to the vent plate 800 and the protruding electrode 820.

As shown in FIG. 19, when the substrate G is placed on the first electrode 410, the first lower lift 510 connected to the bottom of the first electrode 410 moves up and the first electrode 410 is disposed at a predetermined distance from the insulating member 200 at the upper portion in the chamber 100.

Subsequently, the reactive gas flows into the chamber 100 through the inner electrode 310. Aground potential is applied to the inner electrode 310, the outer electrode 320, and the second electrode 420, and RF is applied to the first electrode to generate plasma in the chamber 100. Therefore, particles and thin films accumulated on the edge area of the upper surface, the side, and the edge area of the lower surface of the substrate G are removed by the plasma.

As shown in FIG. 20, when the substrate G is placed on the second electrode 420, the insulating member 200 is disposed at a predetermined distance from the second electrode 420 by the upper lift 600 connected to the insulating member 200. Subsequently, the reactive gas is supplied into the space 314 in the inner electrode 310 through the gas supply channel 110 formed in the chamber lid 100b from the gas supplier 120 connected to the upper portion of the chamber 100. The reactive gas then flows into the chamber 100 through the gas injection nozzle 312 at a side of the inner electrode 310.

The ground potential is applied to the inner electrode 310 and the outer electrode 320 and therefore the ground potential is applied to the chamber liner 700 electrically connected to the outer electrode 320. In addition, the ground potential is also applied to the first electrode 410, and RF is applied to the second electrode 420 to generate plasma P in the chamber 100.

The plasma P is generated in a space surrounded by the second electrode 420, the chamber liner 700 and the protruding electrode 820, the ground potential being applied to the second electrode 420 and the chamber liner 700. Therefore, the plasma P is generated the edge area of the upper surface, the side, and the central portion of the lower surface of substrate G where the ground potential is applied. The plasma P is not generated in the region between the insulating member 200 and the central portion of the upper surface of the substrate G because the distance between the insulating member 200 and the central portion of the upper surface of the substrate G is maintained at 1 mm or less. Therefore, the plasma P generated as described above removes particles and thin films accumulated on the edge area of the upper surface, the side, and the central portion of the lower surface of the substrate G.

According to the above configuration, the upper lift 600 is connected to the insulating member 200 and the first lower lift 510 is connected to the first electrode 410. Thereby, particles and thin films accumulated on the edge area of the upper surface, the side, and the lower surface of the substrate G.

An apparatus according to the above configuration can be easily controlled compared to the lift member according to the first exemplary embodiment of the present invention. The lift member according to the first exemplary embodiment is used for moving the first and second electrodes. The components are therefore concentrated in the lower portion of the chamber and the control of the lift member is not easy, whereas the lift member according to the second exemplary embodiment can avoid the difficulties.

Although a lower lift is connected to the lower portion of a first electrode and an electrode support is connected to a second electrode in the above description, the electrode support may be connected to the first electrode and the lower lift may be connected to the second electrode.

Although a liner which is electrically connected to an outer electrode is provided in the chamber and the ground potential is applied to the liner in the above description, an electrode to which the ground voltage is applied may be formed instead of the liner.

Although a plurality of lower electrodes is coaxially disposed in the above description, the present invention is not limited thereto. The lower electrodes may be arranged in one direction.

Although the process is performed by employing a seesaw structure to a plurality of divided lower electrodes in the above description, but the present invention is not limited thereto. The plurality of electrodes may simultaneously move up depending on various processes.

Although a semiconductor wafer is used as a substrate in the plasma processing apparatus of the above description, but a glass substrate for a flat panel display may be used as a substrate.

Although a plasma processing apparatus of an RIE type having a plurality of lower electrodes according to an exemplary embodiment of the present invention is described in the above description, but the present invention is not limited thereto. The present invention can also be applied to any plasma processing apparatus employing inductive coupled plasma (ICP); capacitively coupled plasma (CCP); electron cyclotron resonance (ECR) plasma using a microwave; surface wave plasma (SWP); and remote plasma system (RPS).

As described above, according to an aspect of the present invention, the plasma processing apparatus effectively removes particles accumulated in a central region of a lower surface of a substrate, in addition to an edge area of an upper surface, a side, and an edge area of a lower surface of the substrate.

Further, a separate lift pin can be omitted, since a substrate can be seated without interference of a robot arm by reducing a size of a lower electrode.

Although the present invention has been described in connection with the exemplary embodiments of the present invention, it will be apparent to those skilled in the art that various modifications and changes may be made thereto without departing from the scope and spirit of the invention.

1. A plasma processing apparatus comprising:
a chamber;
an insulating member disposed in an upper portion of the chamber;
a ground electrode formed at an inner wall of the chamber, a ground potential being applied to the ground electrode; and
a lower electrode disposed at a lower portion of the chamber, a substrate being placed on the lower electrode,
wherein the lower electrode is divided into a plurality of electrodes.

2. The apparatus of claim 1, wherein the plurality of electrodes includes an inner electrode and an outer electrode, and
the inner electrode and the outer electrode are coaxially arranged and spaced apart from each other.

3. The apparatus of claim 2, wherein the distance between the inner electrode and the outer electrode is in a range of 0.1 mm to 10 mm

4. The apparatus of claim 2, further comprising:
a lift member disposed under the lower electrode to move the lower electrode up and down,
wherein the lift member alternately moves the inner electrode and the outer electrode up and down.

5. The apparatus of claim 1, wherein the ground electrode is further formed between the insulating member and an inner wall of the chamber;
a space into which gas is supplied is formed in the ground electrode; and
the space is connected to a gas supplier.

6. The apparatus of claim 5, wherein the ground electrode comprises a gas injection nozzle which is connected to the space and introduces gas into the chamber.

7. The apparatus of claim 4, further comprising:
an upper lift member moving the insulating member up and down,
wherein the lift member is connected to the inner electrode.

8. The apparatus of claim 7, wherein the outer electrode is supported by an electrode support,
a focus ring is further provided around the outer circumference of the outer electrode, and
a vent plate is further provided between the focus ring and the inner wall of the chamber.

9. The apparatus of claim 1, wherein gas injection holes are formed in at least one of the plurality of the electrodes.

10. The apparatus of claim 1, wherein electrode RF power is supplied to at least one of the plurality of electrodes.

11. The apparatus of claim 2, further comprising an intermediate electrode between the inner electrode and the outer electrode.

12. The apparatus of claim 11, further comprising a lift member disposed under the lower electrode to move the lower electrode up and down,
wherein the lift member alternately moves the inner and outer electrodes up and down.

13. The apparatus of claim 11, wherein a diameter of the intermediate electrode is in a range of 56% to 70% of a diameter of the outer electrode, and
a diameter of the inner electrode is in a range of 40% to 56% of the diameter of the outer electrode.

14. The apparatus of claim 11, wherein the diameter of the inner electrode is in a range of 120 mm to 170 mm,
the diameter of the intermediate electrode is in a range of 170 mm to 210 mm, and
the diameter of the outer electrode is in a range of 210 mm to 300 mm.

15. The apparatus of claim 11, wherein the distances between the inner electrode and the intermediate electrode, and between the intermediate electrode and the outer electrode are in a range of 0.1 mm to 10 mm.

16. The apparatus of claim 1, wherein the insulating member includes an inner insulating member and an outer insulating member which is coupled to an outer circumference of the inner insulating member.

17. The apparatus of claim 16, wherein a groove and a protrusion corresponding to each other are formed on an upper surface of the insulating member and a lower surface of the chamber lid, respectively, and
the upper surface of the insulating member is coupled to the lower surface of the chamber lid.

18. The apparatus of claim 16, wherein a gas injector ring is further provided to a lower surface of the inner insulating member.

19. The apparatus of claim 17, wherein a lower groove having a shape of a looped curve is formed on the lower surface of the inner insulating member, and
the gas injector ring is inserted into the lower groove.

20. The apparatus of claim 19, wherein a gas line is further formed through the insulating member to communicate with the lower groove.
